(19) United States
(12) Patent Application Publication
(10) Pub. No.: US 2021/0375646 A1
(43) Pub. Date: Dec. 2, 2021

(54) GAS INJECTOR FOR SEMICONDUCTOR MANUFACTURING CHAMBER

(71) Applicant: RUNSEA TECHNOLOGY CO., LTD., Hsinchu City (TW)

(72) Inventor: Yung-Chiang LIN, Hsinchu City (TW)

(21) Appl. No.: 17/110,817

(22) Filed: Dec. 3, 2020

(30) Foreign Application Priority Data
May 29, 2020 (TW) 109118118

(51) Int. Cl. H01L 21/67; B05B 1/18

(52) U.S. Cl. CPC H01L 21/67017; B05B 1/185

(57) ABSTRACT

A gas injector includes a first and a second columnar body. The first columnar body has a first light-permeable portion, a first outer peripheral surface, a first end surface, and a first flow channel. The first outer peripheral surface has a second flow channel in communication with the first flow channel. The first end surface has a third flow channel. The second and the third flow channels lie in the first light-permeable portion. The second columnar body is connected to the first columnar body, lies in the first flow channel, and has a second light-permeable portion, a second outer peripheral surface, and a fourth and a fifth flow channel. The fourth flow channel is in communication with the third and the fifth flow channels and lies in the second light-permeable portion. The second to the fourth flow channels can be inspected through the light-permeable portions.

### BACKGROUND OF THE INVENTION

### 1. Technical Field

The present invention relates to an injector and more particularly to a gas injector for a semiconductor manufacturing chamber.

### 2. Description of Related Art

The increasing precision of semiconductor manufacturing processes has given rise to more and more rigorous manufacturing process requirements. For example, in cases where the manufacture of a semiconductor structure involves injecting different gases into a semiconductor manufacturing chamber in order for the gases to react with one another to form the semiconductor structure, the gases used must meet stringent purity requirements. The purpose of using high-purity gases is to reduce impurities that may have negative effects on the manufacturing process, and to thereby enhance the controllability of the entire manufacturing process so that the semiconductor structure can be made with precision in a steady manner.

In addition to using high-purity gases, the paths through which the gases are injected must also be controlled to prevent impurities from entering the gases, and only then can the gas purity in the semiconductor manufacturing chamber meet the purity requirements. The gas injectors provided in the semiconductor manufacturing chamber play an important role in controlling the environment of the gas injection paths. The gas injectors are essential to the uniformity and controllability of the flow field in the semiconductor manufacturing chamber because the different kinds of gases must be regulated by their respective injectors before being injected into the semiconductor manufacturing chamber. After the chemical reactions of the gases, however, the flow channels in the injectors may be corroded or have impurities deposited therein. It is therefore imperative to prevent the injectors from being contaminated.

Besides, during the manufacturing process of the gas injectors themselves, manufacturing defects such as a broken or damaged flow channel may have appeared, resulting in contamination of the gases through the manufacturing defects and hence contamination of the semiconductor manufacturing process through the injectors.

### BRIEF SUMMARY OF THE INVENTION

The primary objective of the present invention is to provide a gas injector for a semiconductor manufacturing chamber, wherein the gas injector allows a user to inspect the conditions of the flow channels of the gas injector in order to determine whether the gas injector is good for use or whether, or when, the gas injector needs replacement, thereby preventing contamination attributable to the injector.

The gas injector provided by the present invention for a semiconductor manufacturing chamber includes a first columnar body and a second columnar body. The first columnar body has a first light-permeable portion, a first outer peripheral surface, a first end surface, and a first flow channel. The outer peripheral surface of the first columnar body is formed with at least one second flow channel, and the second flow channel is in communication with the first flow channel. The first end surface of the first columnar body has at least one third flow channel, and both the second flow channel and the third flow channel are located in the first light-permeable portion. The second, columnar body has a second light-permeable portion, a second outer peripheral surface, at least one fourth flow channel, and a fifth flow channel. The second columnar body is connected to the first columnar body and is located in the first flow channel. The fourth flow channel is in communication with the third flow channel, and the fifth flow channel is in communication with the fourth flow channel. The fourth flow channel is located in the second light-permeable portion.

The foregoing design allows a user to inspect the conditions of the second flow channel, the third flow channel, and the fourth flow channel through the first light-permeable portion and the second light-permeable portion, in order to determine whether the gas injector is good for use or whether, or when, the gas injector needs replacement, lest the injector result in contamination.

The first columnar body and the second columnar body may be integrally formed to reduce the chance of cross-contamination between the gas flowing through the first flow channel and the gas flowing through the fifth flow channel.

Moreover, the first outer peripheral surface of the first columnar body may be protrudingly provided with a flange that is formed with a groove to facilitate installation of the gas injector and placement of a sealing element.

The first end surface of the first columnar body may further have a third light-permeable portion, with the third flow channel located in the third light-permeable portion so that a user can inspect the condition of the third flow channel through the third light-permeable portion.

In addition, the present invention provides another gas injector for a semiconductor manufacturing chamber, wherein the gas injector includes a first columnar body that has a first light-permeable portion, a first outer peripheral surface, a first end surface, and a first flow channel. The first outer peripheral surface or the first end surface of the first columnar body is formed with at least one second flow channel in communication with the first flow channel, and the second flow channel is located in the first light-permeable portion.

The foregoing design allows a user to inspect the condition of the second flow channel through the first light-permeable portion in order to determine whether the gas injector is good for use or whether, or when, the gas injector needs replacement, lest the injector result in contamination.

### BRIEF DESCRIPTION OF THE SEVERAL VIEWS OF THE DRAWINGS

FIG. 1 is a perspective view of the gas injector according to the first embodiment of the present invention.

FIG. 2 is a side view of the gas injector according to the first embodiment of the present invention.

FIG. 3 is a sectional view of the gas injector according to the first embodiment of the present invention.

FIG. 4 is a side view of a variant of the gas injector according to the first embodiment of the present invention, wherein the variant has a different first light-permeable portion and a different second light-permeable portion from those in FIG. 2.

FIG. 5 is a perspective view of the gas injector according to the second embodiment of the present invention, wherein the gas injector has a third light-permeable portion.

FIG. 6 is a perspective view of a variant of the gas injector according to the second embodiment of the present invention, wherein the variant has a different third light-permeable portion from that in FIG. 5.

FIG. 7 is a perspective view of the gas injector according to the third embodiment of the present invention.

FIG. 8 is a sectional view of the gas injector according to the third embodiment of the present invention.

FIG. 9 is a perspective view of a variant of the gas injector according to the third embodiment of the present invention.

FIG. 10 is a sectional view of the variant in FIG. 9.

### DETAILED DESCRIPTION OF THE INVENTION

To better demonstrate the technical features of the present invention, the following embodiments are described with reference to the accompanying drawings.

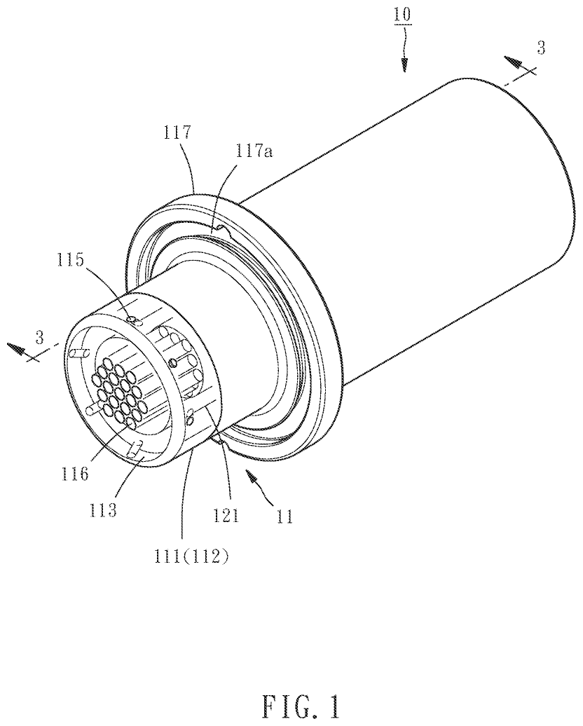

According to the first embodiment of the present invention as shown in FIG. 1 to FIG. 4, the gas injector 10 for a semiconductor manufacturing chamber includes a first columnar body 11 and a second columnar body 12.

It should be pointed out that a manufacturer may choose to make the first columnar body 11 or the second columnar body 12 out of a light-permeable material, such as yttrium aluminum garnet (YAG), in order to provide light permeability. In this embodiment, both the first columnar body 11 and the second columnar body 12 are made of the light-permeable material by way of example.

In this embodiment, given a 1-mm path length of light propagation, the light-permeable material has an internal transmission of 50% to 60% for light with a 200-nm wavelength, an internal transmission >90% for light with a 5000-nm wavelength, and an internal transmission of 3% to 8% for light with a 7500-nm wavelength.

It should also be pointed out that the entire gas injector 10 may be made directly of the light-permeable material without any surface grinding, or a certain surface area of the gas injector 10 may be ground to make it easier to inspect the internal structure of the gas injector 10.

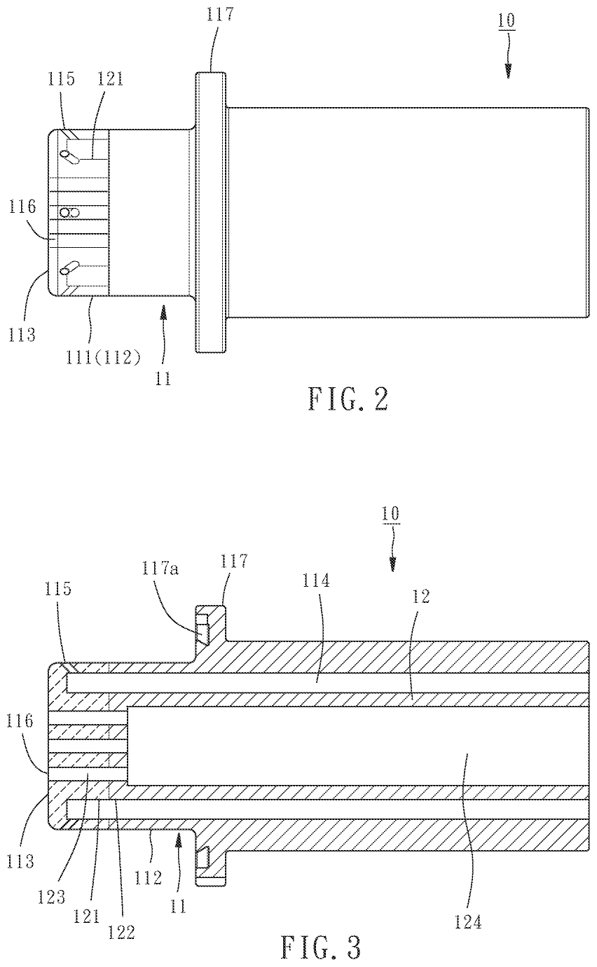

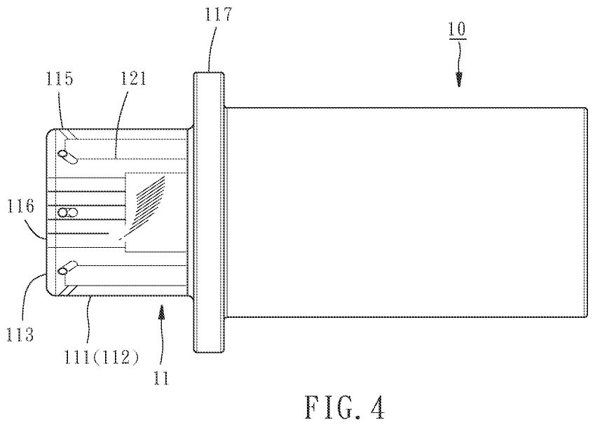

The first columnar body 11 has a first light-permeable portion 111, a first outer peripheral surface 112, a first end surface 113, and a first flow channel 114. The first light-permeable portion 111 may be formed at any part of the first columnar body 11, so that particular part of the first columnar body 11 allows passage of light. There is, however, no limitation on the light-permeability, or lack thereof, of another part of the first columnar body 11. The first light-permeable portion 111 shown in FIG. 4 has a different length from that of the first light-permeable portion 111 shown in FIG. 2. To facilitate passage of light and hence inspection through the first light-permeable portion 111, the first light-permeable portion 111 in this embodiment has received surface grinding as mentioned in the previous paragraph.

The first outer peripheral surface 112 of the first columnar body 11 is formed with at least one second flow channel 115. The second flow channel 115 is in communication with the first flow channel 114 so that a gas flowing into the first flow channel 114 can flow out into a semiconductor manufacturing chamber through the second flow channel 115.

The first end surface 113 of the first columnar body 11 has at least one third flow channel 116. The second flow channel 115 and the third flow channel 116 are located in the first light-permeable portion 111 so that the conditions of the second flow channel 115 and the third flow channel 116 can be inspected with ease.

The second columnar body 12 has a second light-permeable portion 121, a second outer peripheral surface 122, at least one fourth flow channel 123, and a fifth flow channel 124.

The second columnar body 12 is connected to the first columnar body 11 and is located in the first flow channel 114.

The fourth flow channel 123 is in communication with the third flow channel 116, and the fifth flow channel 124 is in communication with the fourth flow channel 123. The fourth flow channel 123 is located in the second light-permeable portion 121. The gas in the fifth flow channel 124 can flow sequentially into the fourth flow channel 123 and the third flow channel 116 before flowing out of the third flow channel 116.

It is worth mentioning that the first columnar body 11 and the second columnar body 12 in this embodiment are integrally formed. This configuration eliminates any seam between the first columnar body 11 and the second columnar body 12 and thereby reduces the chance of cross-contamination between the gas flowing through the first flow channel 114 and the gas flowing through the fifth flow channel 124.

The gas injector 10 provided by this embodiment is so designed that a user can inspect the conditions of the second flow channel 115, the third flow channel 116, and the fourth flow channel 123 through the first light-permeable portion 111 and the second light-permeable portion 121. If there is any manufacturing defect, corrosion, or deposited impurity in the second flow channel 115. the third flow channel 116, or the fourth flow channel 123, the user will be able to determine whether the gas injector is good for use or whether, or when, the gas injector needs to be replaced, lest the injector cause further contamination.

It is also worth mentioning that the first outer peripheral surface 112 of the first columnar body 11 may be protrudingly provided with a flange 117, and the flange 117 is formed with a groove 117a. The grooved flange design makes it easy to install the gas injector and mount a sealing element on the gas injector.

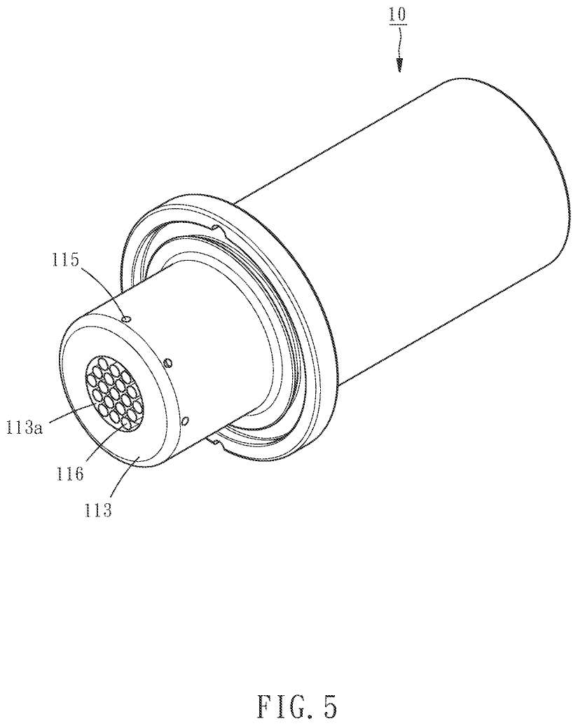

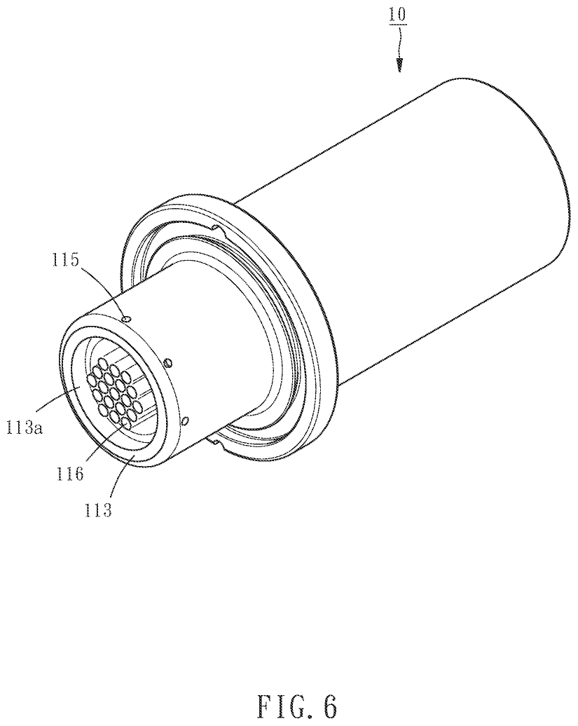

Please refer to FIG. 5 and FIG. 6 for the gas injector 20 provided by the second embodiment of the present invention for a semiconductor manufacturing chamber. The second embodiment is different from the first embodiment in that the first end surface 113 of the first columnar body 11 further has a third light-permeable portion 113a, and the third flow channel 116 is located in the third light-permeable portion 113a so that the condition of the third flow channel 116 can be inspected with ease. The third. light-permeable portion 113a is a part of the first columnar body 11 that allows passage of light, and there is no limitation on the light-permeability, or lack thereof, of another part of the first columnar body 11. The gas injector 20 provided by this embodiment allows a user to inspect the condition of the third flow channel 116 through the third light-permeable portion 113. If there is any manufacturing defect, corrosion, or deposited impurity in the third flow channel 116, the user will be able to determine whether the gas injector is good for use or whether, or when, the gas injector needs to be replaced, lest the injector cause further contamination.

The third light-permeable portion 113a shown in FIG. 6 has a different size from the third light-permeable portion 113a shown in FIG. 5.

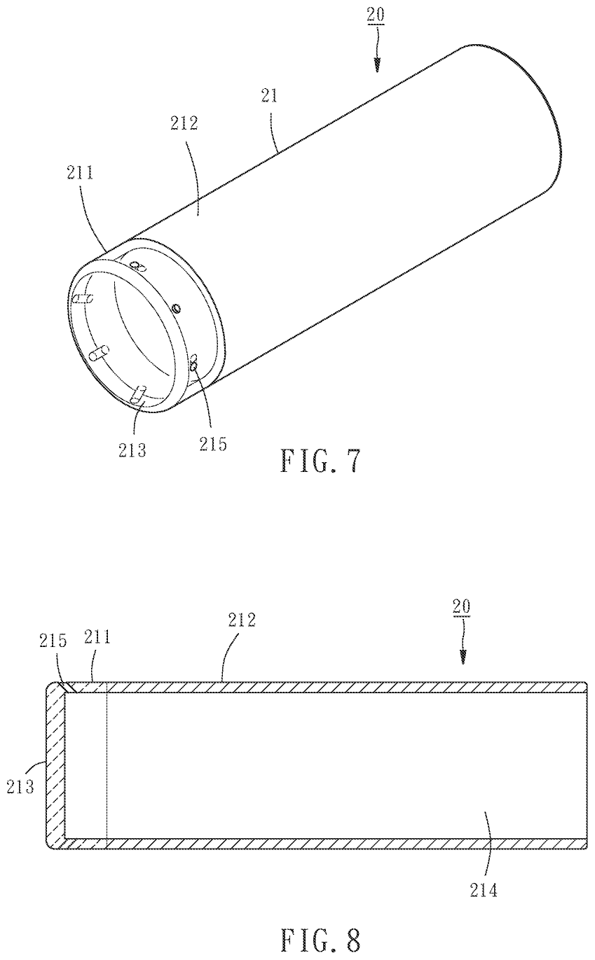

Please refer to FIG. 7 to FIG. 10 for the gas injector 20 provided by the third embodiment of the present invention for a semiconductor manufacturing chamber. This embodiment is a simplified version of the first embodiment and includes a first columnar body 21.

In this embodiment, the first columnar body 21 is made of a light-permeable material by way of example. The entire gas injector 20 may be made directly of the light-permeable material without any surface grinding, or a certain surface area of the gas injector 20 may be ground to make it easier to inspect the internal structure of the gas injector 20.

The first columnar body 21 has a first light-permeable portion 211, a first outer peripheral surface 212, a first end surface 213 and a first flow channel 214.

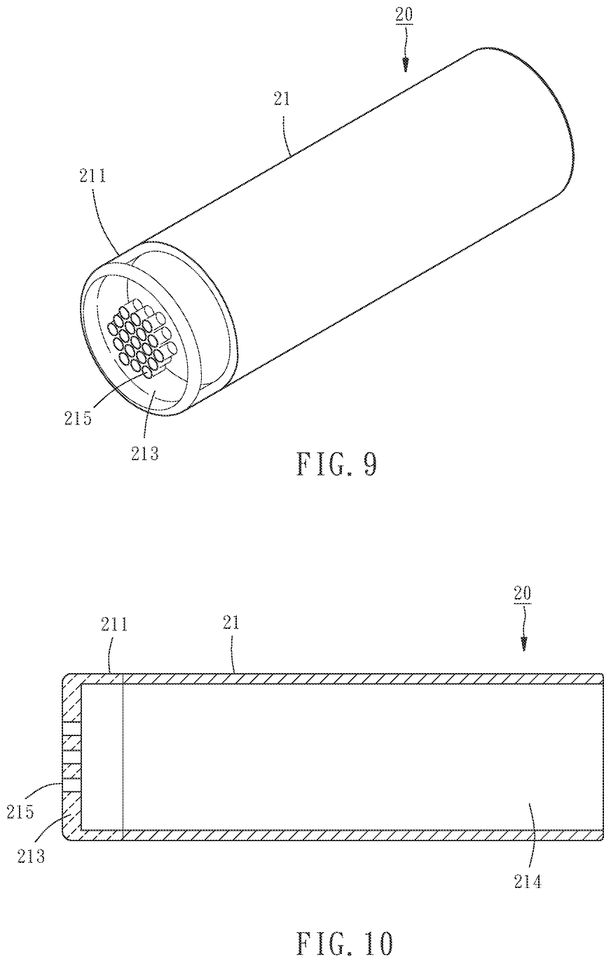

The first light-permeable portion 211 may be formed at any part of the first columnar body 21, so that particular part of the first columnar body 21 allows passage of light. There is, however, no limitation on the light-permeability, or lack thereof, of another part of the first columnar body 21. The first light-permeable portion 211 shown in FIG. 9 is located differently from the first light-permeable portion 211 shown in FIG. 7. To facilitate passage of light and hence inspection through the first light-permeable portion 211, the first light-permeable portion 211 in this embodiment has received surface grinding.

The first outer peripheral surface 212 (see FIG. 7) or the first end surface 213 (see FIG. 9) of the first columnar body 21 is formed with at least one second flow channel 215. The second flow channel 215 is in communication with the first flow channel 214 so that a gas flowing into the first flow channel 214 can flow out into a semiconductor manufacturing chamber through the second flow channel 215.

The gas injector 20 provided by this embodiment allows a user to inspect the condition of the second flow channel 215 through the first light-permeable portion 211. If there is any manufacturing defect, corrosion, or deposited impurity in the second flow channel 215, the user will be able to determine whether the gas injector is good for use or whether, or when, the gas injector needs to be replaced, lest the injector cause further contamination.

What is claimed is:

1. A gas injector for a semiconductor manufacturing chamber, comprising:
a first columnar body having a first light-permeable portion, a first outer peripheral surface, a first end surface, and a first flow channel, wherein the first outer peripheral surface of the first columnar body is formed with at least one second flow channel, the second flow channel is in communication with the first flow channel, the first end surface of the first columnar body has at least one third flow channel, and the second flow channel and the third flow channel are located in the first light-permeable portion; and
a second columnar body having a second light-permeable portion, a second outer peripheral surface, at least one fourth flow channel, and a fifth flow channel, wherein the second columnar body is connected to the first columnar body and is located in the first flow channel, the fourth flow channel is in communication with the third flow channel, the fifth flow channel is in communication with the fourth flow channel, and the fourth flow channel is located in the second light-permeable portion.

2. The gas injector for the semiconductor manufacturing chamber as claimed in claim 1, wherein the first columnar body or the second columnar body is made of a light-permeable material, and given a 1-mm path length of light propagation, the light-permeable material has an internal transmission of 50% to 60% for light with a 200-nm wavelength, an internal transmission >90% for light with a 5000-nm wavelength, and an internal transmission of 3% to 8% for light with a 7500-nm wavelength.

3. The gas injector for the semiconductor manufacturing chamber as claimed in claim 1, wherein the first columnar body and the second columnar body are integrally formed.

4. The gas injector for the semiconductor manufacturing chamber as claimed in claim 1, wherein the first outer peripheral surface of the first columnar body is protrudingly provided with a flange, and the flange is formed with a groove.

5. The gas injector for the semiconductor manufacturing chamber as claimed in claim 1, wherein the first end surface of the first columnar body further has a third light-permeable portion, and the third flow channel is located in the third light-permeable portion.

6. A gas injector for a semiconductor manufacturing chamber, comprising:
a first columnar body having a first light-permeable portion, a first outer peripheral surface, a first end surface, and a first flow channel, wherein the first outer peripheral surface or the first end surface of the first columnar body is formed with at least one second flow channel, the second flow channel is in communication with the first flow channel, and the second flow channel is located in the first light-permeable portion.

7. The gas injector for the semiconductor manufacturing chamber as claimed in claim 6, wherein the first columnar body is made of a light-permeable material and given a 1-mm path length of light propagation, the light-permeable material has an internal transmission of 50% to 60% for light with a 200-nm wavelength, an internal transmission >90% for light with a 5000-nm wavelength, and an internal transmission of 3% to 8% for light with a 7500-nm wavelength.
